(19) United States
(12) Patent Application Publication
(10) Pub. No.: US 2021/0396796 A1
(43) Pub. Date: Dec. 23, 2021

(54) METHOD, MEASURING DEVICE AND DATA CARRIER WITH MEASUREMENT DATA FOR DETERMINING THE INDUCTANCE OF AN ELECTRICAL COMPONENT

(71) Applicant: BS & T Frankfurt am Main GmbH, Frankfurt am Main (DE)

(72) Inventors: Jun-Chao SUN, Frankfurt am Main (DE); Christian TESKE, Basingstroke (GB)

(73) Assignee: BS & T Frankfurt am Main GmbH, Frankfurt am Main (DE)

(21) Appl. No.: 17/290,548

(22) PCT Filed: Nov. 1, 2019
(86) PCT No.: PCT/EP2019/079987

§ 371 Date: Jun. 30, 2021

(30) Foreign Application Priority Data
Nov. 2, 2018 (DE) 10 2018 127 378.9

(51) Int. Cl. G01R 27/26; G01R 15/18; G01R 15/06

(52) U.S. Cl. CPC G01R 27/2611; G01R 15/06; G01R 15/181

(57) ABSTRACT

Determining the inductance L of an electrical component includes a high current pulse being generated and conducted through the electrical component. The electronic component is arranged in an electrical resonant circuit, in series with a reference component and with at least one capacitor. The resonant circuit is excited to oscillate by the high current pulse. Electrical properties of the electrical component are measured for a measuring duration, and the inductance L of the electrical component is determined from the measured electrical properties. A voltage drop U across the electrical component and a reference voltage drop U_{R} across the reference component having a known reference inductance L_{R} is measured. The inductance L of the electrical component is calculated as a product of the reference inductance L_{R} with a proportionality factor, which is dependent on the measured voltage drop U and the measured reference voltage drop U_{R}.

### CROSS-REFERENCE TO RELATED APPLICATION

This application is a national stage application, filed under 35 U.S.C. § 371, of International Patent Application No. PCT/EP2019/079987, filed on Nov. 1, 2019, which claims the benefit of German Patent Application No. 10 2018 127 378.9, filed Nov. 2, 2018.

### TECHNICAL FIELD

The disclosure relates to a method for determining the inductance of an electrical component. The disclosure also relates to a measuring device for determining the inductance of an electrical component, by means of which measuring device the disclosed method can be performed. The disclosure furthermore relates to a data medium comprising measuring data from which the inductance of an electrical component can be determined.

### BACKGROUND

The electrical properties of an electrical component which can be used in a device that is supplied with electrical energy are of decisive importance for the electrical component in question. This also applies analogously for electronic components and electronic circuits, which will not be mentioned and described separately in the following but rather referred to in a simplified and summarizing manner as electrical circuits and electrical components.

In this case, the use of soft magnetic materials is increasingly gaining significance for the manufacture and design of compact and low-loss electrical components, and in particular in electrical components in the field of power electronics which can be used for shaping of electrical energy with respect to the voltage waveform, the magnitude of voltage and current, and the frequency. In this case, in many situations the saturation behavior and a power loss, occurring during operation, of a soft magnetic material are important properties of an inductive electrical component produced from or using a soft magnetic material of this kind. The inductive properties of soft magnetic materials of this kind, or very generally of magnetic materials, are therefore detected using a range of measuring methods and measuring devices, in order to be able to identify materials that are as suitable as possible for the relevant intended use of an electrical component.

In this case, a challenge in terms of measuring technology when detecting the inductive properties of magnetic materials and in particular of soft magnetic materials is the often high field strengths of several 100 kA/m and a correspondingly large current flow, which are required in many cases in order to be able to detect the non-linear behavior and in particular the saturation behavior of soft magnetic materials. During the measuring process, a measurement current of several thousand amperes, or several kA, must flow through the electrical component, in order to be able to detect the inductive properties, as a result of which, however, a very significant portion of the electrical energy is often simultaneously converted into heat energy, and as a result the temperature of the electrical component is increased during the measuring process. This routinely leads to a change in the electrical properties and to an error in the determination of the electrical properties, in particular the inductance, of soft magnetic materials and electrical components produced therefrom.

In this case, it must be taken into account that, in the case of electrical components comprising soft magnetic materials, the inductive properties thereof often do not exhibit linear behavior but rather, for example, non-linear saturation behavior, at high currents, and the energy losses arising during operation are dependent on a temporal change in the current flow in question.

Various methods are known in practice, by means of which the inductance of an electrical component can be determined. In this case, in particular pulse methods are suitable, in which methods a pulsed current flow through the electrical component is generated, and the relevant electrical properties of the electrical component, typically arranged in a resonant circuit, are detected. As a result of a large pulsed current flow, which is generated for a short time, an electrical oscillation, which subsequently dies away in a damped manner, is excited in the electrical resonant circuit, which oscillation can be used for carrying out the required measurements. On account of the non-continuous, but rather short-term, application of the pulsed current flow, only slight heating occurs when measuring electrical components comprising soft magnetic materials, such that the measurement results are not, or at least barely, influenced by a temperature change during the measurement.

In a suitable measuring device for pulse methods of this kind, the electrical component is arranged in a resonant circuit, wherein the measuring device comprises a current source which can be connected to the resonant circuit and by means of which a high current pulse in the resonant circuit can be generated, and wherein a voltage drop U across the electrical component can be measured using a voltmeter. During performance of the measuring method, after the excitation of the high current pulse, electrical properties of the electrical component are measured in a measuring step, for a measuring duration, wherein in an evaluation step the inductance L of the electrical component can be determined from the measured electrical properties.

The inductance L describes the correlation of a temporally varying rate of change of the electrical current dI(t)/dt with respect to the electrical voltage U(t) induced by the change in the electrical current I(t). In the event of a temporally non-varying inductance, the inductance can be specified as a proportionality constant L. The voltage U(t) induced by a change in the electrical current I(t) can be described as the product of the inductance L and the rate of change of the current d_{I} (t)/dt:

$$U ( t ) = L \frac{dI ( t )}{d t}$$

Therefore, in the measuring methods known from practice, in order to determine the inductance L both a voltage drop U(t) across the electrical component and a current flow I(t) through the electrical component are measured, and the inductance is calculated from the measured values for the voltage drop U(t) and the temporal change in the current flow dI(t)/dt, wherein the rate of change of the current flow dI(t)/dt is not measured directly but rather determined from the measured current flow I(t). However, the calculation of the inductance L from the measured voltage drop U(t) and the relevant current flow I(t) through the electrical component is associated with a comparatively large degree of metrological uncertainty.

### SUMMARY

An object of the present disclosure is therefore considered that of amending and developing a measuring method described above in such a way that as precise as possible a determination of the electrical properties, and in particular the inductance, of an electrical component is made possible using the simplest possible means.

This object is achieved in that, in the measuring step, a voltage drop U across the electrical component and a reference voltage drop U_{R} across a reference component connected in series with the electrical component and having a known reference inductance L_{R} is measured, and wherein in the evaluation step the inductance L of the electrical component is calculated as a product of the reference inductance L_{R} with a proportionality factor, which is dependent on the measured voltage drop U and the measured reference voltage drop U_{R}. The measurement of a voltage drop can typically be carried out in a manner requiring substantially less metrological complexity, and substantially more precisely, than the determination of a rate of change of the current flow which is determined by measuring a temporally variable current flow over the measuring duration and subsequent estimation of a likewise temporally variable rate of change of the current flow. In other measuring methods, integration of the measured current flow I(t) over the measuring duration is required, as a result of which significant uncertainties and systematic errors are also created or at least promoted.

It has been shown that, as a result of using a reference component, the simultaneous measurement of the voltage drop across the electrical component and across the reference component allows for a particularly precise determination of the inductance of the electrical component. In this case, the resonant circuit in which the electrical component and the reference component are arranged is expediently designed such that a damped oscillation is excited by the high current pulse, and the two voltage drops are detected in a temporally resolved manner, over at least a few oscillation amplitudes. In this case, the damping of the resonant circuit is advantageously sufficiently great that the electrical oscillations in the resonant circuit die away quickly, and a thermal load of the electrical component is as small as possible.

The high current pulse can advantageously have a current intensity of several kA and be adjusted to the magnetic properties of the electrical component, the inductance of which is intended to be determined. In particular in the case of electrical components comprising soft magnetic materials, it may be advantageous to use a high current pulse having a current intensity of several kA, in order to be able to determine the saturation behavior of the soft magnetic materials and a typically non-linear behavior of the soft magnetic materials.

In order to improve the measuring accuracy, it can optionally be provided to additionally also measure a current flow I(t) through the electrical component during the measuring step. The measured current flow can be used for checking the measured values for the voltage drops in the electrical component and in the reference component. It is also possible to detect further electrical properties of the resonant circuit using the measured current flow and to take these into account when determining the inductance L of the electrical component.

According to a particularly advantageous embodiment of the inventive concept it is provided, for this purpose, that, in the evaluation step, the proportionality factor is calculated as a quotient of, on the one hand, the difference between the measured voltage drop U and the product of the ohmic resistance R of the electrical component and the measured current flow I, and, on the other hand, the measured reference voltage drop U_{R}. This correlation can be specified as follows:

$$L = {L}_{R} \frac{( U ( t ) - RI ( t ) )}{{U}_{R} ( t )}$$

In particular for the event of the electrical resistance R of the electrical component having a noticeable effect on the electrical properties thereof in the case of use of the electrical component as intended, it is advantageous to take into account the ohmic resistance R when determining the inductance L of the electrical component.

On account of one embodiment of the inventive concept, the ohmic resistance R can be determined relatively precisely as the average of the quotients of the voltage drop U and the current flow Iₚₑₐₖ at a plurality of amplitude maxima of the current flow I through the electrical component during the measuring duration, wherein the measuring duration comprises some amplitude maxima of the damped oscillation of the electrical resonant circuit:

$$R = \frac{U ( {I}_{p e a k} )}{{I}_{p e a k}}$$

The amplitude maxima Iₚₑₐₖ of the current flow I constitute extreme points in which the influence of the inductance L on the current flow through the electrical component can be briefly ignored, and the ohmic resistance R of the electrical component results, to a good approximation, from the quotient from the measured voltage drop U and the measured current flow I. Forming an average value for the ohmic resistance R thus calculated, over several amplitude maxima or extreme points of the current flow, makes it possible to improve the accuracy when determining the ohmic resistance R.

The inductance L of the electrical component can then be calculated as a product of the known inductance L_{R} with the quotient from the difference U−RI on the one hand, and the voltage drop U_{R} on the other hand, as is summarised in the formula described below, wherein the inductance L is determined as a function of the current flow I(t) excited by the high current pulse Iₚᵤₗₛ:

$$L ( {I}_{puls} ) = {L}_{R} \frac{( U ( t ) - RI ( t ) )}{{U}_{R} ( t )}$$

In this case, the difference U−RI corresponds to the electromotive force. If the inductance L were to have a linear dependency on the current flow, and accordingly no saturation behavior, the inductance L would be the same for different high current pulses. On account of the saturation behavior at high current flows, which is pronounced in particular in the case of soft magnetic materials, the inductance L exhibits a dependency on the current flow, or on the specified high current pulse, which can be detected and evaluated by measurements having high current pulses that are specified at different magnitudes.

Proceeding from the values measured over the measuring duration for the voltage drops U and U_{R} and for the current flow I, it is additionally possible for further characteristic electrical properties of the electrical component to be determined. For example, the insertion loss a_{I} for a specified high current pulse Iₚᵤₗₛ can be determined from the logarithm of a quotient of two measured extreme values U₁ and U₂ of successive amplitude maxima U₁ and U₂ of the measured voltage drop, wherein the extreme value U₁ of the larger value, in terms of amount, of a temporally earlier amplitude maximum of the damped oscillation progression of the measured voltage drop U(t) is:

$${a}_{I} ( {I}_{puls} ) = 20 log \vert \frac{{U}_{1}}{{U}_{2}} \vert$$

In order to determine the extreme values or the amplitude maxima of the voltage curve U(t) it is possible, in the case of automated performance of the determination method, to use the same algorithm as for the determination of the amplitude maxima of the temporal progression of the current flow I(t) for the determination of the ohmic resistance R. It is also conceivable for the extreme values U₁ and U₂, just like the amplitude maxima, of the temporally variable current flow I(t), to be manually determined or specified.

It is thus possible for an energy loss EL dependent on the current flow to be determined for example by evaluating the measured values over a half-wave of the voltage and current progressions during an oscillation that dies away in a damped manner, which energy loss is of particular significance for the operation of an electrical component, comprising soft magnetic materials, in power electronics. In this case, the energy loss EL results from the product of the voltage and current progression, integrated over a half-wave between two successive amplitude maxima U₁ and U₂ of the voltage drop across the electrical component, according to the following formula:

EL=∫_{t(U}_{₁}₎^{t(U}^{₂}⁾(U(t)*I(t))dt

In order to keep as low as possible an undesired influence of the excitation step, or in the case of triggering the high current pulse, on the resonant circuit, it is optionally possible for the high current pulse to be triggered, during the excitation step, by a controller which is galvanically isolated from the circuit comprising the electrical component. The control signals of the controller can be transmitted for example by means of suitable fiber optics or via optical fibers, which are arranged between suitable optocouplers.

In the case of a measuring device according to the invention for determining the inductance of the electrical component, the electrical component is arranged in a resonant circuit. The measuring device comprises a current source which can be connected to the resonant circuit and by means of which a high current pulse can be generated in the resonant circuit. A voltage drop U across the electrical component can be measured using a suitable voltmeter.

Whereas in the case of the measuring devices known from practice generally just one ammeter is provided and the inductance L is determined or derived from the measured voltage drop U(t) and the measured current flow I(t) through the electrical component, the measuring device according to the invention comprises a reference component having a reference inductance L_{R}, which reference component is arranged in the resonant circuit so as to be in series with the electrical component, and a reference voltage device by means of which a reference voltage drop U_{R} across the reference component can be measured. The simultaneous measurement of the two voltage drops, U across the electronic component and U_{R} across the reference component, can be carried out in a very precise manner using simple means. In many cases for example a digital oscilloscope can be used, which has a plurality of measuring channels.

The reference component can, in an advantageous manner, take on the function of a safety inductor, which is arranged in the resonant circuit and is dimensioned such that, in the case of the high current pulse, both the maximally occurring peak amplitude of the high current pulse and the current slew rate in the resonant circuit can be suitably set or limited.

According to an advantageous embodiment of the inventive concept, the reference component is an air coil. The inductance of an air coil which has no magnetic, and in particular no soft magnetic, core, can be determined very precisely by means of previously performed measurements. Furthermore, non-linear effects can often be ignored in the case of an air coil. Furthermore, an air coil can be effectively cooled with little outlay, such that even in the case of a high current flow no undesired temperature change of the reference component, and no influencing of the measured values, brought about thereby, need to be feared.

Optionally, it may additionally be provided that a current flow through the electrical component can be measured using an ammeter. An additional measurement of the current flow through the electrical component makes it possible for further characteristic properties of the electrical component to be detected or to be determined from the additionally measured time-dependent measured values for the current flow. The ammeter can for example be a toroidal air coil, which is arranged around the current-carrying conductor. A measuring means of this kind is also referred to as a Rogowski coil or as a Rogowski current transformer. It is also possible to use a comparable coil having a magnetic core, wherein a coil of this kind is also referred to as a Pearson coil.

According to one embodiment of the inventive concept, the high current pulse required for exciting the resonant circuit can be generated in a structurally simple manner in that the measuring device comprises a controller and a capacitor that is arranged in the resonant circuit, wherein the capacitor can be charged by a charging device in a first control state of the controller, and wherein the capacitor is discharged in the resonant circuit in a second control state of the controller, and subsequently electrical oscillations can be performed in the resonant circuit. In the first control state, discharge of the capacitor via the resonant circuit must be prevented by the controller, in order that the capacitor can be charged via the charging device. A charging capacitor can be connected to the resonant circuit, and in particular to the capacitor, as a charging device, such that electrical charge previously stored in the charging capacitor can be transferred to the capacitor, in order to charge said capacitor such that a high current pulse can be output from the capacitor into the resonant circuit. The charging capacitor can be charged by a suitable charging circuit having a voltage source provided therefor.

It is preferably provided for the controller to comprise a thyristor which is arranged in the resonant circuit and can be activated by the controller. A thyristor can be controlled by the controller in a simple manner, such that the thyristor blocks the resonant circuit in the first control state of the controller and does not allow any current flow in the resonant circuit, and releases the resonant circuit following activation of the thyristor, and thereby makes it possible for the high current pulse to excite the electrical resonant circuit and for the damped electrical oscillations to subsequently occur.

In order to reduce an undesired influence of the controller on the resonant circuit it is provided, according to an embodiment of the inventive concept, for the controller to be galvanically isolated from the resonant circuit.

The invention also relates to an electronically readable data medium comprising a data sequence stored therein, wherein the data sequence comprises at least one measuring data packet having an item of high current pulse information and having two measurement series of a temporal progression of a voltage drop U(t) and of a reference voltage drop U_{R}(t) for an electrical resonant circuit, excited using the high current pulse, having an electrical component and having a reference component which was excited to a damped electrical oscillation by the high current pulse. The data sequence of the at least one measuring data packed has preferably been determined using the method described above. Optionally, a measuring device, also described above, may have been used for the detection of the measuring data. Proceeding from the measuring data of a measuring data packet, numerous different electromagnetic properties of the electrical components examined in each case can be determined and calculated. In this case, the available options for retrospective evaluation and determination of properties of the electrical components extend far beyond the options available in the case of conventional measuring data packets. In this way, soft magnetic materials can be categorised for use in electrical components, and the corresponding electrical components can be standardised or normed. Furthermore, the measuring data packets can be used to carry out a substantially more meaningful comparison of the measured measuring data with theoretical models on electromagnetic properties of electrical components and in particular of electrical components comprising soft magnetic materials.

It is optionally possible, according to the invention, for a measuring data packet to additionally comprise a measurement series of a temporal progression of a current flow through the electrical component.

### BRIEF DESCRIPTION OF THE DRAWINGS

Exemplary embodiments of the inventive concept will be explained in greater detail in the following, said embodiments being shown in the drawings, in which:

FIG. 1 is a schematic illustration of a measuring device according to the invention which is suitable for carrying out the measurement method according to the invention,

FIG. 2 shows a measuring device in greater detail,

FIG. 3 is a schematic view of the temporal progression of the measured voltage drop U across the electrical component, of the measured reference voltage drop U_{R} across the reference component, and of the measured current flow I during a damped oscillation which was excited by means of a high current pulse in an electrical resonant circuit, and

FIG. 4 is a schematic illustration of the inductance, determined for various amplitude maxima of the current flow, as a function of the current flow.

### DETAILED DESCRIPTION

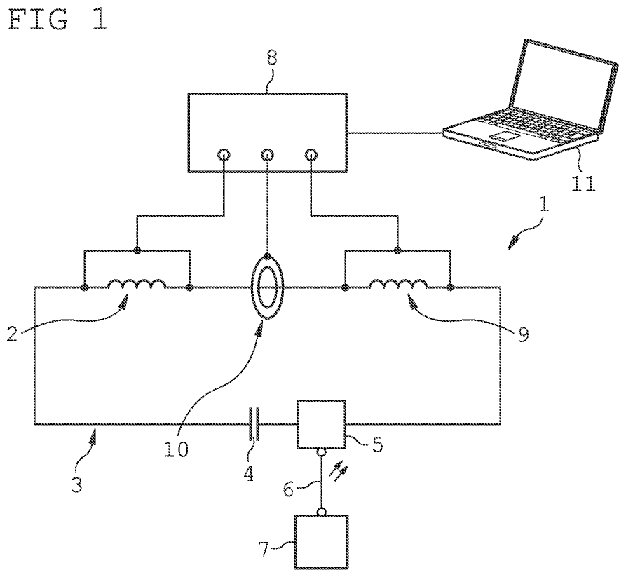

A measuring device 1, shown schematically in FIG. 1, for determining the inductance L of an electrical component 2, comprises an electrical resonant circuit 3 in which a capacitor 4 is arranged, in addition to the electrical component 2. The capacitor 4 can be charged using a suitable charging device 5. The charging device 5 is connected to a controller 7 by means of a fibre-optic waveguide 6. In a first control state of the controller 7, the capacitor 4 is charged by the charging device 5. If the controller 7 switches into a second control state, the electrical resonant circuit 3 is released and a high current pulse is generated in the electrical resonant circuit by the sudden discharge of the previously charged capacitor 4, which high current pulse excites a damped electrical oscillation in the electrical resonant circuit 3.

During the dying away electrical oscillation in the electrical resonant circuit 3, a voltage drop U(t) across the electrical component 2, the inductance L of which is intended to be determined, is measured using a digital oscilloscope 8.

In addition to the electrical component 2, a reference component 9 is arranged in the electrical resonant circuit 3. The reference component 9 also has an inductance L_{R} which has been determined in advance by suitable measurements. A voltage drop U_{R}(t) across the reference component can be measured via a further measuring channel, by means of the digital oscilloscope 8. If an ohmic resistance R in the electrical resonant circuit 3, or in particular in the electrical component 2, can be ignored, the sought inductance L of the electrical component 2 can be calculated approximately as a product of the known inductance L_{R} of the reference component 9 and the quotient of the measured voltage drops U(t)/U_{R}(t):

$$L = {L}_{R} \frac{U ( t )}{{U}_{R} ( t )}$$

In addition to the electrical component 2, an ammeter 10 designed for example as a Rogowski coil or Pearson coil is arranged in the electrical resonant circuit 3, the measured values of which ammeter can also be detected and evaluated using the digital oscilloscope 8. A current flow I(t) through the electrical component 2 is measured by the ammeter 10 during the electrical oscillations in the electrical resonant circuit 3. During the electrical oscillations, the ohmic resistance R of the electrical component 2 can be calculated, at the extreme points of the successive amplitude maxima Iₚₑₐₖ of the temporally variable current flow I(t), as a quotient of the voltage drop U(t=t(Iₚₑₐₖ)) at one extreme point Iₚₑₐₖ and the current flow I(t=t(Iₚₑₐₖ)) at the extreme point. Averaging for a plurality of successive extreme points or amplitude maxima of the current flow makes it possible for the ohmic resistance R, determined therefrom, to be further specified.

An evaluation of the measured values, measured over the measuring duration, for the two voltage drops U(t) and U_{R}(t), and optionally for the current flow I(t), can be carried out by means of a suitable data processing facility 11 or an evaluation software executed thereon. In this case, the sought inductance L of the electrical component 2 can be determined as a product of the known inductance L_{R} of the reference component 9 and a proportionality factor, wherein the proportionality factor results in the quotient of the difference between the measured voltage drop U across the electrical component 2 and the voltage drop R I across the ohmic resistance of the electrical component 2 on the one hand, and the measured voltage drop U_{R} across the reference component 9 on the other hand. The calculation can be summarised by the formula set out in the following:

$$L ( I ) = {L}_{R} \frac{( U ( t ) - RI ( t ) )}{{U}_{R} ( t )} \qquad$$

In this case, the inductance L of the electrical component 2 is substantially dependent on the current flow I in question. Furthermore, in particular in the case of electrical components comprising soft magnetic materials, on account of the non-linear saturation behaviour, the inductance is also dependent on the relevant high current pulse or on a current flow brought about through the electrical component, directly prior thereto.

If the electrical component 2 comprises an inductive component having a soft magnetic material, it is expedient for the electrical resonant circuit 3 to be excited to electrical oscillation by a high current pulse of several kA.

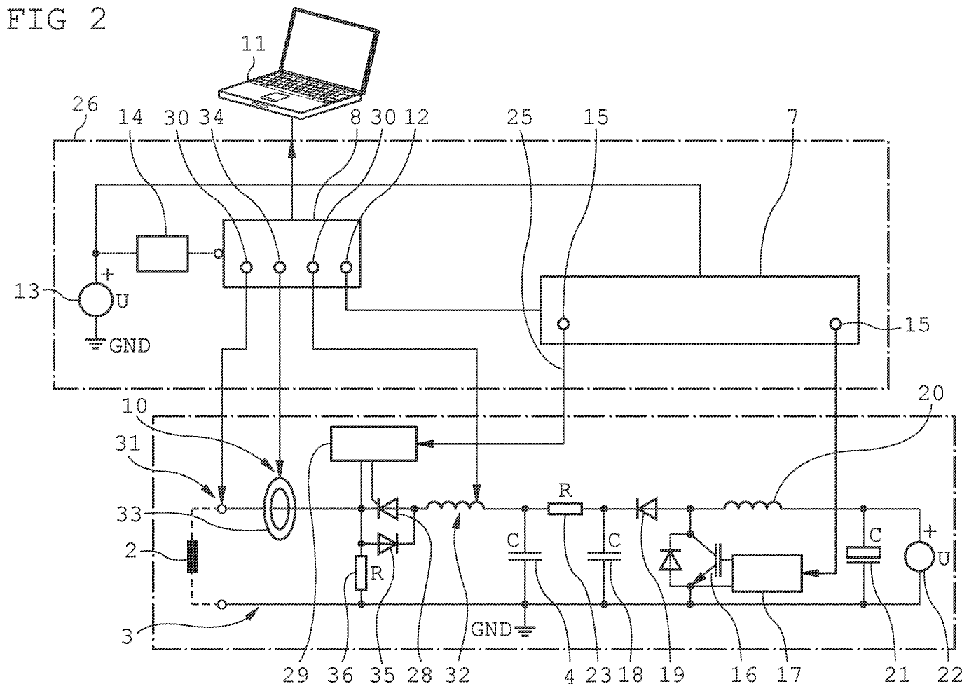

The performance of a measurement for determining the inductance L of the electrical component 2 is explained on the basis of measuring device 1 shown in slightly more detail in FIG. 2. By means of a suitable software, the digital oscilloscope 8 receives, via an interface, a command from the data processing means 11 for generating an electrical control signal at one of the waveform outputs 12 thereof. Said control signal is forwarded to the controller 7 for high current pulse generation. Both the digital oscilloscope 8 and the controller 7 are connected to a voltage source 13 by suitable connections. A DC-to-DC converter 14 converts an output voltage of the voltage source 13 into an input voltage suitable for the digital oscilloscope 8. Depending on the duration of the control signal, a boost converter or a step-up converter (16, 17, 18, 19, 20, 21, 22) is actuated via a fibre-optic output 15 by means of pulse wave modulation generated by the controller 7, which converter charges the capacitor 4 to a voltage suitable for the high current pulse, via a charging resistor 23.

The boost converter preferably comprises an IGBT 16, a fibre-optic optocoupler 17, a charging capacitor 18, a diode 19, an inductive component 20, a capacitor 21, and a suitable voltage supply 22. Fibre-optic signal lines 24 and 25 ensure a galvanically isolated connection between a control and evaluation circuit 26 and an impulse and measuring circuit 27, and minimise the influence of electromagnetic interference signals which may arise in the impulse and measuring circuit 27. For reasons of operating safety, a common reference potential or a common earthing can be provided.

As soon as the control signal of the digital oscilloscope 8 is ended, the control signal transitions into a negative flank. Said negative flank deactivates the pulse wave modulation for the boost converter and activates a temporal sequence, stored in the controller 7, which activates a high current thyristor 28 via the galvanically isolated fibre-optic signal line 25. The control current for a thyristor 28 is generated by a fibre-optic signal processing means 29. Instead of a high current thyristor 28, another suitable control circuit can also be used, which circuit for example comprises an insulated-gate bipolar transistor (IGBT) or a metal-oxide-semiconductor field-effect transistor (MOSFET).

As a result, a high current pulse is generated and an electrical oscillation excited in the electrical resonant circuit 3. The electrical resonant circuit comprises the capacitor 4, the reference component 9, and the electrical component 2 to be measured. Both the maximally occurring peak amplitude of the current flow in the case of the high current pulse, and the rate of change of the current flow dI(t)/dt can be specified, and in particular limited, by means of suitable dimensioning of the reference component 9.

The voltage drop U across the electrical component 2 and the voltage drop U_{R} across the reference component is detected via analogue inputs 30 of the digital oscilloscope 8, using suitable voltmeters 31, 32. The current flow I(t) through the electrical component is detected via a further analogue input 34 of the digital oscilloscope 8, using a suitable ammeter 10 which for example comprises a Pearson coil 33.

Since in most cases the resulting resonant circuit is undercritically damped, a flyback diode 35 allows for a current reversal and thus bipolar actuation of the electrical component, which is advantageous for numerous applications, such as for detecting the saturation behaviour of the electrical component.

The capacitor 4 can be discharged via a suitable resistor 36, by activating the thyristor 28. In this case, the resistor 36 should be dimensioned such that the impedance thereof is relatively large compared with the electrical component 2.

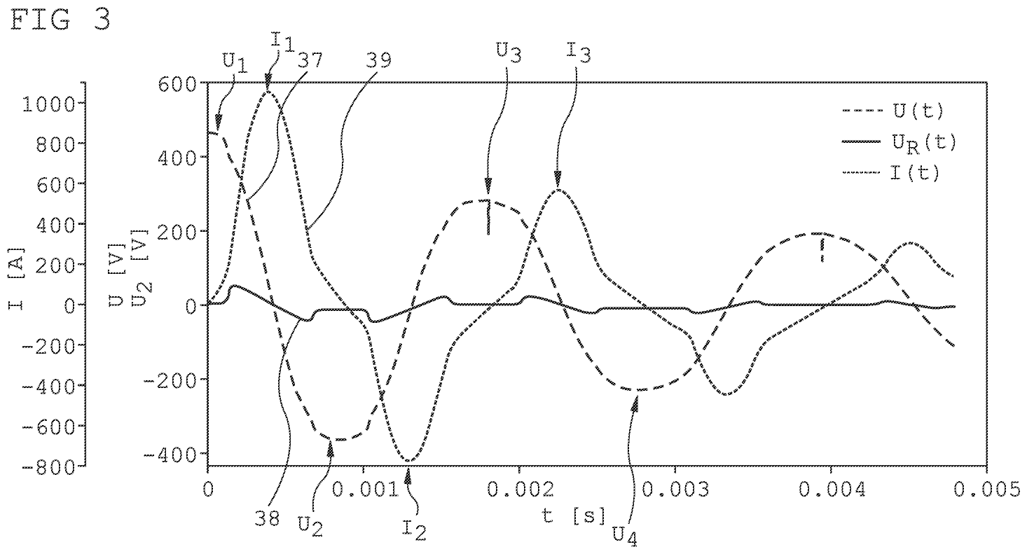

FIG. 3 shows, by way of example, the temporal progression, over a plurality of oscillations of the electrical resonant circuit 3, of the voltage U(t) 37 that drops across the electrical component 2, the reference voltage U_{R}(t) 38 that drops across the reference component 9, and the current flow I(t) 39 flowing through the electrical component 2. The successive extreme points U₁, U₂, U₃ etc. and I₁, I₂, I₃ etc. of the individual temporal progressions can be determined by suitable mathematical methods. At the extreme points of the current flow, the ohmic resistance R of the electrical component 2 can in each case be determined, and averaged over a plurality of extreme points. Proceeding from two successive extreme values U₁, U₂, U₃ etc., in each case, for the voltage drop U(t), the insertion loss a_{I}(Iₚᵤₗₛ) can be determined, the insertion loss a_{I}(Iₚᵤₗₛ) being dependent on the extreme value of the maximum current flow, proceeding from which the insertion loss a_{I}(Iₚᵤₗₛ) is determined.

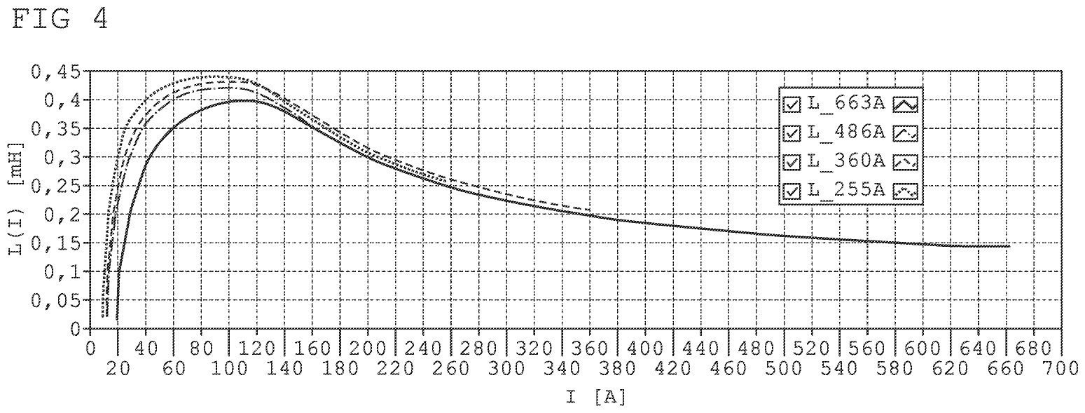

For each half-wave following an extreme point of the current flow I₁, I₂, I₃ etc., the inductance L(Iₚᵤₗₛ=I₁, I₂, I₃ etc.) that is dependent on the temporally changing progression of the current flow I(t) can be determined. For a plurality of successive extreme points of the temporal progression shown in FIG. 3, of the damped oscillation in the electrical resonant circuit 3, the relevant inductance L(I) is shown schematically, as a function of the current, in FIG. 4. In this case, the inductance L(I) is not the same for a specified current I, in particular at a comparatively low current flow of up to 150 A, but rather greatly dependent on the maximum value of the current flow at the preceding extreme point I₁, I₂, I₃ etc. of the current flowing through the electrical component 2 during the damped oscillation. Using this information on the saturation behaviour of the electrical component 2, and the inductance or the energy losses EL of the electrical component 2 during a current flow, new electrical components can be designed such that they are adjusted as best as possible for the relevant intended purpose, in particular in terms of power electronics.

1.-14. (canceled)

15. A method for determining the inductance (L) of an electrical component (2), comprising:
connecting a reference component (9) having a known reference inductance (L_{R}) in series with the electrical component (2);
generating, in an excitation step, a high current pulse and conducting the high current pulse through the electrical component (2);
measuring, in a measuring step, electrical properties of the electrical component (2) for a measuring duration; and
determining, in an evaluation step, the inductance (L) of the electrical component (2) from the measured electrical properties,
wherein, in the measuring step, a voltage drop (U) across the electrical component (2) and a reference voltage drop (U_{R}) across the reference component (9) are measured, and
wherein, in the evaluation step, the inductance (L) of the electrical component (2) is calculated as a product of the reference inductance (L_{R}) with a proportionality factor, which is dependent on the measured voltage drop (U) and the measured reference voltage drop (U_{R}).

16. The method according to claim 15,
wherein, during the measuring step, a current flow (I) through the electrical component (2) is also measured.

17. The method according to claim 16,
wherein, in the evaluation step, the proportionality factor is calculated as a quotient of,
the difference between the measured voltage drop (U) and the product of the ohmic resistance (R) of the electrical component (2) and the measured current flow (I), and
the measured reference voltage drop (U_{R}).

18. The method according to claim 17,
wherein the ohmic resistance is determined as the average of the quotients of the voltage drop (U) and the current flow (I) at a plurality of amplitude maxima of the current flow (I) through the electrical component (2) during the measuring step.

19. The method according to claim 15,
wherein, during the excitation step, the high current pulse is triggered by a controller (7) which is galvanically isolated from a circuit comprising the electrical component (2).

20. The method according to claim 15,
wherein an energy loss is determined as a product of the voltage and current progression, integrated over a half-wave between two successive amplitude maxima (U1 and U2) of the voltage drop across the electrical component.

21. A measuring device (1) for determining the inductance of an electrical component (2),
wherein the electrical component (2) is arranged in a resonant circuit (3),
wherein the measuring device comprises a current source which can be connected to the resonant circuit (3) and by means of which a high current pulse in the resonant circuit (3) can be generated,
wherein a voltage drop (U) across the electrical component (2) can be measured using a voltmeter (31),
wherein a reference component (9) having a reference inductance (L_{R}) is arranged in series with the electrical component (2), in the resonant circuit (3), and
wherein a reference voltage drop (U_{R}) across the reference component (9) is measured using a reference voltmeter (32).

22. The measuring device (1) according to claim 21,
wherein the reference component (9) is an air coil.

23. The measuring device (1) according to claim 21,
wherein a current flow through the electrical component (2) is measured by an ammeter (33).

24. The measuring device (1) according to claim 21,
wherein the measuring device (1) comprises a controller (7) and a capacitor (4) that is arranged in the resonant circuit (3),
wherein the capacitor (4) is charged by a charging device (5) in a first control state of the controller (7), and
wherein the capacitor (4) is discharged in the resonant circuit (3) in a second control state of the controller (7), and subsequently electrical oscillations are performed in the resonant circuit (3).

25. The measuring device (1) according to claim 24,
wherein the controller (7) comprises a thyristor (28) which is arranged in the resonant circuit (3) and configured to be activated by the controller (7).

26. The measuring device (1) according to claim 24,
wherein the controller (7) is galvanically isolated from the resonant circuit (3).

27. An electronically readable data medium comprising a data sequence stored therein,
wherein the data sequence comprises at least one measuring data packet having an item of high current pulse information and having two measurement series of a temporal progression of a voltage drop (U(t)) and of a reference voltage drop (U_{R}(t)) for an electrical resonant circuit, excited using the high current pulse, having an electrical component and having a reference component which was excited to a damped electrical oscillation by the high current pulse.

28. The electronically readable data medium according to claim 27,
wherein a measuring data packet stored thereon further comprises a measurement series of a temporal progression of a current flow through the electrical component.
